(19) United States
(12) Patent Application Publication
(10) Pub. No.: US 2025/0309004 A1
(43) Pub. Date: Oct. 2, 2025

(54) METHOD OF MANUFACTURING SILICON CARBIDE SEMICONDUCTOR DEVICE

(71) Applicant: DENSO CORPORATION, Kariya-city (JP)

(72) Inventor: Yusuke HAYAMA, Kariya-city (JP)

(21) Appl. No.: 19/236,084

(22) Filed: Jun. 12, 2025

Related U.S. Application Data
(63) Continuation of application No. PCT/JP2023/042091, filed on Nov. 23, 2023.

(30) Foreign Application Priority Data
Dec. 14, 2022 (JP) 2022-199525

(51) Int. Cl. H01L 21/66; H10D 30/66; H10D 62/832

(52) U.S. Cl. CPC H01L 22/12; H10D 62/8325; H10D 30/668

(57) ABSTRACT

In a method of manufacturing a silicon carbide semiconductor device having a switching element on a semiconductor substrate made of silicon carbide to have a built-in diode, measuring a BPD density which is a density of basal plane dislocation in the semiconductor substrate; predicting an energization fluctuation quantity based on at least the BPD density, the energization fluctuation quantity being an amount of fluctuation in electrical characteristics after the switching element is driven for a predetermined time relative to an initial value of electrical characteristics of the switching element immediately after a semiconductor chip having the switching element is manufactured; and determining whether or not to continue manufacturing the silicon carbide semiconductor device using the semiconductor substrate based on the energization fluctuation quantity.

### CROSS REFERENCE TO RELATED APPLICATION

The present application is a continuation application of International Patent Application No. PCT/JP2023/042091 filed on Nov. 23, 2023, which designated the U.S. and claims the benefit of priority from Japanese Patent Application No. 2022-199525 filed on Dec. 14, 2022. The entire disclosures of all of the above applications are incorporated herein by reference.

### TECHNICAL FIELD

The present disclosure relates to a method of manufacturing a silicon carbide (hereinafter referred to as SiC) semiconductor device.

### BACKGROUND

A metal oxide semiconductor field effect transistor (MOSFET) is included in a SiC semiconductor device made of SiC. In the SiC semiconductor device, a built-in diode is formed by a pn junction between a base layer and a drift layer. In this type of SiC semiconductor device, basal plane dislocations (hereinafter referred to as BPDs) may exist in the SiC substrate.

### SUMMARY

According to one aspect of the present disclosure, in a method of manufacturing a silicon carbide semiconductor device having a switching element on a semiconductor substrate made of silicon carbide to have a built-in diode, measuring a BPD density which is a density of basal plane dislocation in the semiconductor substrate; predicting an energization fluctuation quantity based on at least the BPD density, the energization fluctuation quantity being a fluctuation amount of electrical characteristics after the switching element is driven for a predetermined time or more relative to an initial value of electrical characteristics of the switching element immediately after a semiconductor chip having the switching element is manufactured; and determining whether or not to continue manufacturing the silicon carbide semiconductor device using the semiconductor substrate based on the energization fluctuation quantity.

### BRIEF DESCRIPTION OF THE DRAWINGS

FIG. 1 is a perspective cross-sectional view showing a SiC semiconductor device.

FIG. 2 is a cross-sectional view showing a cell region of a semiconductor chip made of SiC.

FIG. 3 is an explanatory diagram of a current path in the semiconductor chip.

FIG. 4 is an explanatory diagram of defect growth caused by BPD.

FIG. 5 is a flowchart showing a part of a manufacturing process of a SiC semiconductor device according to an embodiment.

FIG. 6 is a graph showing a relationship between a BPD density of a SiC semiconductor substrate and a change in Von of MOSFET of a semiconductor chip manufactured using the SiC semiconductor substrate.

FIG. 7 is a diagram showing a band-shaped defect and a triangular defect that grew from BPD, using a PL imaging method.

FIG. 8A is a diagram showing an example of distribution of BPD density in a SiC semiconductor substrate.

FIG. 8B is a diagram showing another example of distribution of BPD density in a SiC semiconductor substrate.

FIG. 9 is a flowchart showing a manufacturing process of a SiC semiconductor device, following FIG. 5.

FIG. 10 is a diagram showing an example of variation in initial electrical characteristics of a semiconductor chip.

FIG. 11 is a cross-sectional view showing a SiC semiconductor device according to another embodiment, corresponding to FIG. 2.

### DETAILED DESCRIPTION

A SiC semiconductor device is made of SiC and includes, for example a metal oxide semiconductor field effect transistor (MOSFET). Specifically, in this type of SiC semiconductor device, for example, an n− type buffer layer having a lower impurity concentration than the SiC substrate is formed on an n+ type SiC substrate. An n− type drift layer having a lower impurity concentration than the buffer layer is formed on the buffer layer. A p-type base layer is disposed on the drift layer. The buffer layer and the drift layer are formed of epitaxial layer. An n+ type source region is disposed in a surface layer of the base layer. Plural trenches are provided to penetrate the source region and the base layer and reach the drift layer. A gate insulating film and a gate electrode are sequentially disposed in each of the trenches. As a result, a MOSFET with a trench gate structure is formed.

In the SiC semiconductor device, a built-in diode is formed by a pn junction between the base layer or the like and the drift layer.

In this type of SiC semiconductor device, basal plane dislocations (hereinafter referred to as BPDs) may exist in the SiC substrate. In this type of SiC semiconductor device, driving the built-in diode causes defects to expand in the epitaxial layer starting from the BPD, resulting in a decrease in the amount of current when electricity is passed through the device. Hereinafter, for ease of explanation, an energization fluctuation quantity represents the amount of variation in the electrical characteristics of the built-in diode after the defect expansion caused by the BPDs, relative to the initial value of the electrical characteristics of the built-in diode at the time of manufacturing the SiC semiconductor device.

In recent years, such fluctuations in current are required to be suppressed in the SiC semiconductor device. Therefore, it may be determined whether or not a recombination layer for suppressing the current fluctuation should be provided, based on the BPD density of SiC substrate, when forming an epitaxial layer, so as to determine the configuration of SiC semiconductor device.

When forming a recombination layer having a higher impurity concentration than the SiC substrate in the formation of the epitaxial layer, it is possible to provide a SiC semiconductor device with reduced current fluctuation. However, the manufacturing cost increases. In order to reduce the manufacturing cost, it is desirable to determine whether or not to continue manufacturing the SiC semiconductor device based on the predicted amount of fluctuation in current in the manufacturing process, and to classify SiC chips, on which the MOSFET is formed, according to the required performance.

The present disclosure relates to a method of manufacturing a SiC semiconductor device in which the current fluctuation is suppressed by predicting the current fluctuation and reflecting the predicted current fluctuation in the manufacturing process.

According to one aspect of the present disclosure, a silicon carbide semiconductor device has a switching element formed on a semiconductor substrate made of silicon carbide to have a built-in diode. A method of manufacturing the silicon carbide semiconductor device includes: measuring a BPD density, which is a density of basal plane dislocations in the semiconductor substrate; predicting an energization fluctuation quantity based on at least the BPD density; and determining whether to continue manufacturing the semiconductor device using the semiconductor substrate based on the predicted energization fluctuation quantity. The energization fluctuation quantity represents an amount of fluctuation in electrical characteristics after driving the switching element for a predetermined period of time or more, relative to an initial value of the electrical characteristics of the switching element immediately after manufacturing a semiconductor chip having the switching element.

Accordingly, when a semiconductor chip having a switching element is manufactured using a semiconductor substrate made of SiC, the amount of fluctuation in current of the semiconductor chip is predicted based on at least the BPD density of the semiconductor substrate. Then, by determining whether or not to continue manufacturing the SiC semiconductor device using the semiconductor substrate based on the predicted amount of current fluctuation, it is possible to efficiently manufacture the SiC semiconductor device with a suppressed amount of current fluctuation.

Hereinafter, embodiments of the present disclosure will be described with reference to the drawings. In the embodiments, same or equivalent parts are designated with the same reference numerals.

### First Embodiment

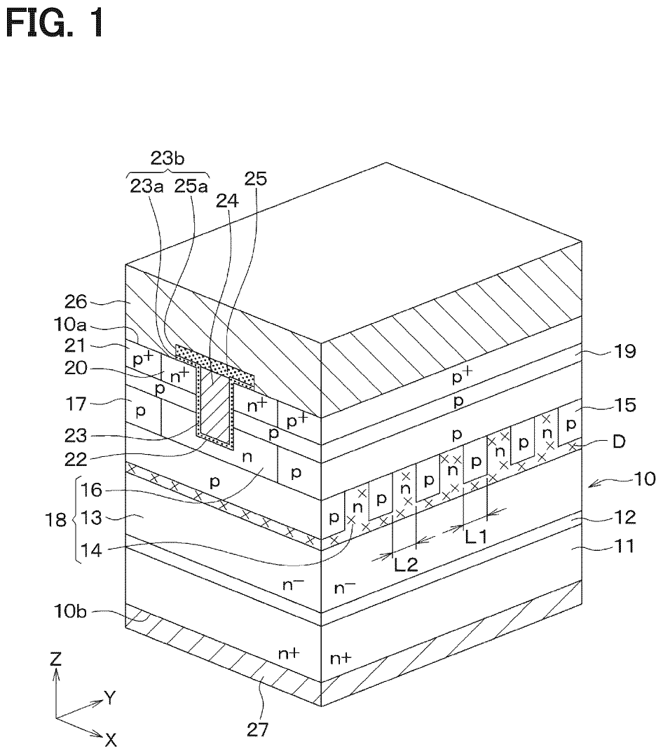

A first embodiment will be described with reference to the drawings. In this embodiment, as shown in FIG. 1, a SiC semiconductor device includes a semiconductor chip 10 in which an inversion type MOSFET having a trench gate structure is formed as a switching element. Although not specifically shown, the semiconductor chip 10 has a cell region and a periphery region formed to surround the cell region. The MOSFET shown in FIG. 1 is formed in the cell region of the semiconductor chip 10.

For ease of explanation, as shown in FIG. 1, one direction in a surface direction of a semiconductor substrate 11 (described later) is referred to as X direction, and a direction perpendicular to the X direction in the surface direction is referred to as Y direction. A direction perpendicular to the surface direction, i.e., the XY plane, is referred to as Z direction.

The SiC semiconductor device includes the semiconductor chip 10. Specifically, the semiconductor chip 10 includes an n+ type semiconductor substrate 11 made of, for example, SiC. The semiconductor substrate 11 is, for example, a SiC substrate having an off angle of 0° to 8° with respect to the (0001) Si-plane. The n-type impurity concentration of nitrogen, phosphorus, or the like is 1.0×10^{19/}cm³, but is not limited thereto. The thickness is about 300 μm, but is not limited thereto. The semiconductor substrate 11 constitutes, for example, a drain region.

An n-type buffer layer 12 made of, for example, SiC is formed on the surface of the semiconductor substrate 11. The buffer layer 12 is formed on the surface of the semiconductor substrate 11 by epitaxial growth. The n-type impurity concentration of the buffer layer 12 is, for example, between the n-type impurity concentration of the semiconductor substrate 11 and the n-type impurity concentration of a low concentration layer 13. The buffer layer 12 has a thickness of about 1 μm.

The n-type low concentration layer 13 made of SiC is formed on a surface of the buffer layer 12. The n− type low concentration layer 13 has an n-type impurity concentration of, for example, 5.0×10¹⁵ to 10.0×10¹⁵/cm³ and a thickness of about 10 to 15 μm. The low concentration layer 13 may have a constant impurity concentration in the Z direction, but it may be preferable that the concentration distribution is gradient. Specifically, the low concentration layer 13 may have a higher concentration on the side adjacent to the semiconductor substrate 11 than the side of the low concentration layer 13 away from the semiconductor substrate 11. For example, it is preferable that a part of the low concentration layer 13 about 3 to 5 μm from the surface of the semiconductor substrate 11 has an impurity concentration higher than that in the other part by about 2.0×10^{15/}cm³. In this case, an internal resistance of the low concentration layer 13 can be reduced, so that the on-resistance can be reduced. The low concentration layer 13 is formed as an epitaxial layer by epitaxial growth.

A JFET portion 14 and a first deep layer 15 are formed in the surface layer of the low concentration layer 13, for example, at a connection between the cell region and the periphery region (not shown). The JFET portion 14 and the first deep layer 15 are alternately arranged in the Y direction. Each of the JFET portion 14 and the first deep layer 15 has a linear portion that extends along the X direction. In other words, the JFET portion 14 and the first deep layer 15 are configured in a stripe shape extending along the X direction, when viewed in the normal direction to the surface of the semiconductor substrate 11. The JFET portion 14 and the first deep layer 15 are arranged alternately in the Y direction. Hereinafter, for ease of explanation, the normal direction to the surface of the semiconductor substrate 11 will also be simply referred to as normal direction.

The JFET portion 14 is, for example, an n-type having a higher impurity concentration than the low concentration layer 13, and has a depth of 0.3 to 1.5 μm. The JFET portion 14 has an n-type impurity concentration of, for example, 7.0×10¹⁶ to 5.0×10¹⁷/cm³. The JFET portion 14 is, for example, an ion-implanted layer formed by ion-implanting n-type impurities into the low concentration layer 13.

The first deep layer 15 has a p-type impurity such as boron with the concentration of 2.0×10¹⁷ to 2.0×10¹⁸/cm³. The first deep layer 15 extends beyond the JFET portion 14 toward a guard ring (not shown) of the periphery region. The first deep layer 15 is formed, for example, shallower than the JFET portion 14. That is, the first deep layer 15 is formed so that its bottom is located within the JFET portion 14. In other words, the JFET portion 14 is located between the first deep layer 15 and the low concentration layer 13. The first deep layer 15 has a width of, for example, 0.9 μm or less, in the Y direction. The pitch between the first deep layers 15 adjacent to each other in the Y direction is, for example, 0.75 to 1.1 μm.

A surface portion of the low concentration layer 13 has plural p-type guard rings (not shown) at, for example, the periphery region (not shown) so as to surround the cell region. The guard ring has, for example, a rectangular shape with rounded corners or a circular shape when viewed in the normal direction.

A current spreading layer 16 and a second deep layer 17 are formed on the JFET portion 14 and the first deep layer 15 in the cell region.

The current spreading layer 16 is made of, for example, an n-type impurity layer and has a thickness of 0.5 to 2 μm. The n-type impurity concentration of the current spreading layer 16 is set to, for example, 1.0×10¹⁶ to 5.0×10¹⁷/cm³. The current spreading layer 16 is connected to the JFET portion 14. Therefore, the low concentration layer 13, the JFET portion 14, and the current spreading layer 16 are connected to each other, to form a drift layer 18.

The second deep layer 17 is formed in the cell region, and has, for example, a p-type impurity concentration of 2.0×10¹⁷ to 2.0×10¹⁸/cm³ and a thickness equal to that of the current spreading layer 16. The second deep layer 17 is formed to be connected to the first deep layer 15.

Each of the current spreading layer 16 and the second deep layer 17 extends in a direction intersecting a part of the JFET portion 14 having the stripe shape, in other words, extends in a direction intersecting the longitudinal direction of the first deep layer 15. In the present embodiment, the current spreading layer 16 and the second deep layer 17 extend along the Y direction as a longitudinal direction, and are alternately arranged in the X direction. A formation pitch between the current spreading layer 16 and the second deep layer 17 is matched to a formation pitch between trench gate structures to be described later, and a trench 22 to be described later is interposed between the second deep layers 17.

A p-type base layer 19 is formed on the current spreading layer 16 and the second deep layer 17. An n+ type source region 20 and a p+ type contact region 21 are formed in a surface layer of the base layer 19 in the cell region. The source region 20 is in contact with a side surface of the trench 22, and the source region 20 is interposed between the contact region 21 and the trench 22. The source region 20 corresponds to an impurity region.

The base layer 19 has, for example, an p-type impurity concentration of 3.0×10¹⁷/cm³ or lower. The base layer 19 is formed by, for example, ion implantation, and the impurity concentration in the cell region is higher than that in the periphery region. The source region 20 has an n-type impurity concentration at the surface layer, in other words, a surface concentration of, for example, 1.0×10²¹/cm³. The contact region 21 has an p-type impurity concentration at the surface layer, in other words, a surface concentration of, for example, 1.0×10²¹/cm³.

The thicknesses of the base layer 19 and the source region 20 are adjusted so that the channel length is, for example, 0.4 μm or less. The channel length is a length of a part of the base layer 19 along the side surface of the trench 22 in the Z direction.

In the semiconductor chip 10, for example, the semiconductor substrate 11, the buffer layer 12, the low concentration layer 13, the JFET portion 14, the first deep layer 15, the current spreading layer 16, the second deep layer 17, the base layer 19, the source region 20, and the contact region 21 are stacked. For ease of explanation, a surface of the semiconductor chip 10 adjacent to the source region 20 and the contact region 21 will be referred to as one surface 10a of the semiconductor chip 10, and a surface adjacent to the semiconductor substrate 11 will be referred to as the other surface 10b of the semiconductor chip 10. The source region 20 and the contact region 21 are exposed from the one surface 10a of the semiconductor chip 10.

In the cell region of the semiconductor chip 10, plural trenches 22 are formed, each having a width of 1.4 to 2.0 μm, to extend through the base layer 19 and the like to reach the current spreading layer 16. The bottom surface of the trench 22 is located within the current spreading layer 16. The trench 22 has a depth not reaching the JFET portion 14 and the first deep layer 15, and is formed so that the JFET portion 14 and the first deep layer 15 are located below the bottom surface of the trench 22.

The trenches 22 are arranged at equal intervals in the X direction in a striped pattern and extend along the Y direction. In other words, the longitudinal direction of the trench 22 is perpendicular to the longitudinal direction of the first deep layer 15. The trench 22 is interposed between the second deep layers 17 as viewed in the normal direction. The trenches 22 are formed so that the distance between the centers of the trenches 22 adjacent to each other, that is, the trench pitch, is 3.0 μm or less.

The trench 22 is filled with, for example, a gate insulating film 23 formed on the inner wall surface and a gate electrode 24 made of doped Poly-Si formed on the surface of the gate insulating film 23. As a result, a trench gate structure is formed. Although not particularly limited, the gate insulating film 23 is formed, for example, by thermally oxidizing the inner wall surface of the trench 22 or by forming a film by CVD. The CVD is an abbreviation for chemical vapor deposition. The gate insulating film 23 has a thickness of, for example, about 100 nm on both the side surface and the bottom surface of the trench 22.

The gate insulating film 23 is formed on the surface of the trench 22 other than the inner wall surface. Specifically, the gate insulating film 23 is formed to cover, for example, a part of the surface of the source region 20 on the one surface 10a of the semiconductor chip 10. In other words, the gate insulating film 23 has a contact hole 23a that exposes the rest of the contact region 21 and the source region 20 at a portion different from the portion where the gate electrode 24 is disposed.

The gate insulating film 23 is formed on the surface of the base layer 19 in the periphery region (not shown). Similarly to the gate insulating film 23, the gate electrode 24 is extended onto the surface of the gate insulating film 23 in the periphery region. The trench gate structure of the present embodiment is formed as described above.

The semiconductor chip 10 has, for example, a mesa structure formed in the periphery region (not shown) in which a recess is formed to penetrate the base layer 19 and reach the current spreading layer 16. In a part of the periphery region adjacent to the cell region, the contact region 21 is formed in the surface layer of the base layer 19, similar to the cell region.

An interlayer insulating film 25 is formed on the one surface 10a of the semiconductor chip 10 to cover the gate electrode 24, the gate insulating film 23, and the like. The interlayer insulating film 25 is made of, for example, borophosphosilicate glass (BPSG).

The interlayer insulating film 25 has a contact hole 25a connected to the contact hole 23a, for exposing the source region 20 and the contact region 21. The contact hole 25a of the interlayer insulating film 25 is formed to communicate with the contact hole 23a of the gate insulating film 23, and functions as one contact hole together with the contact hole 23a. Hereinafter, the contact holes 23a and 25a will be collectively referred to as a contact hole 23b. The pattern of the contact hole 23b is arbitrary, such as a pattern in which plural squares are arranged, a pattern in which rectangular lines are arranged, and a pattern in which lines are arranged. The contact hole 23b is, for example, linear along the longitudinal direction of the trench 22.

A source electrode 26 is formed on the interlayer insulating film 25 to be electrically connected to the source region 20 and the contact region 21 through the contact hole 23b. The source electrode 26 is connected to the contact region 21 formed in the base layer 19 of the periphery region. Moreover, a gate wiring (not shown) is formed on the interlayer insulating film 25 to be electrically connected to the gate electrode 24 through the contact hole 23b.

The source electrode 26 is made of multiple metals such as Ni/Al. Of the multiple metals, a part of the source electrode 26 in contact with n-type SiC, i.e., the portion that constitutes the source region 20, is made of a metal that can make ohmic contact with n-type SiC. A part of the source electrode 26 in contact with at least p-type SiC (in other words, the contact region 21) is made of metal capable of ohmic contact with the p-type SiC.

The drain electrode 27 electrically connected to the semiconductor substrate 11 is formed on the other surface 10b of the semiconductor chip 10. The semiconductor chip 10 has, for example, an n-channel type inversion type trench gate MOSFET. In addition, in the semiconductor chip 10, a built-in diode is formed by a pn junction between the drift layer 18 and the base layer 19.

The above is a basic configuration of the semiconductor chip 10 in the SiC semiconductor device. The SiC semiconductor device is used, for example, by utilizing the MOSFET of the semiconductor chip 10 to configure an inverter circuit for driving a three-phase motor or the like, but is not limited to this use and can be applied to other uses as well.

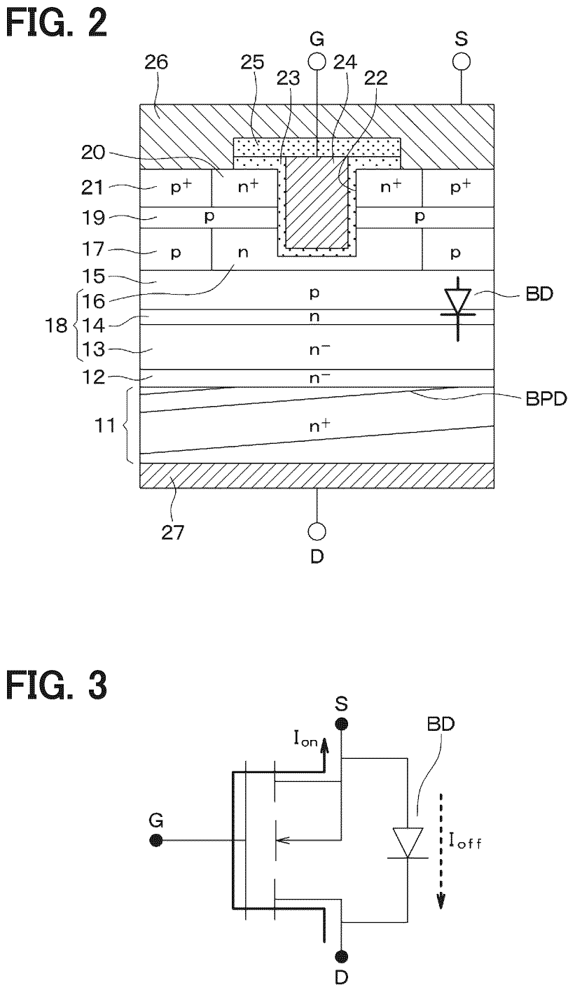

A defect growth due to basal plane dislocations will be described. As shown in FIG. 2, the SiC semiconductor device has the MOSFET with trench gate structure and a built-in diode BD formed of pn junction in the cell region. In the SiC semiconductor device, BPDs exist in, for example, the semiconductor substrate 11, the buffer layer 12, the drift layer, and the like, and defects due to the BPDs can occur.

As shown in FIG. 3, the SiC semiconductor device has a circuit configuration including the MOSFET and the built-in diode BD. When the MOSFET is on, an on-current Iₒₙ flows from the drain electrode 27 to the source electrode 26. In FIG. 3, “S”, “D”, and “G” correspond to the source electrode 26, the drain electrode 27, and the gate electrode 24, respectively. Specifically, when a predetermined voltage, such as 20 V, is applied to the gate electrode 24, a channel is formed on the surface of the base layer 19 in contact with the trench 22, and the on-current lon flows between the source electrode 26 and the drain electrode 27.

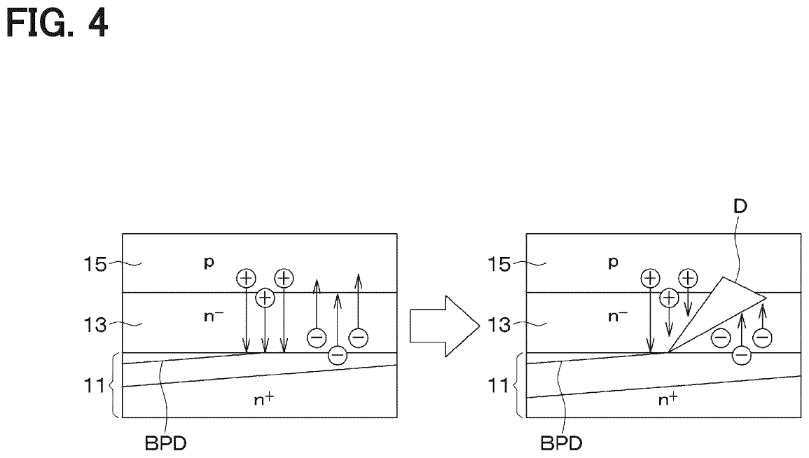

Thereafter, when the SiC semiconductor device is turned off, a reverse bias is applied and the device is in a reverse conducting state, so that the built-in diode BD functions as a freewheeling diode and a freewheeling current loff flows through the built-in diode. At this time, as shown in FIG. 4, holes that have diffused from the p-type layer side to the n-type layer side of the pn junction that constitutes the built-in diode BD recombine with electrons in the n-type layer. Since the recombination energy between holes and electrons is large, the BPDs expand and a stacking fault D occurs in the SiC semiconductor device. Hereinafter, the stacking fault D will be simply referred to as a “defect D.” The defect D interferes with the on-current Iₒₙ and the freewheeling current loff. As described above, when the semiconductor chip 10 is operated for a period of time longer than a predetermined period of time, the defect D occurs. Therefore, the electrical characteristics after operation deteriorate compared to the electrical characteristics immediately after manufacture, i.e., before the defect D occurs.

In recent years, there has been a demand for SiC semiconductor devices to reduce the current fluctuation, which is the amount of variation in electrical characteristics after being driven for a predetermined period of time or more, compared to the initial electrical characteristics of the semiconductor chip 10 before the defect D occurs. The electrical characteristics include, for example, the forward voltage Vf of the built-in diode BD and the voltage V_{DS} when the MOSFET is on. Since the manufacturing cost of the SiC semiconductor device is higher than that of a semiconductor device whose main component is Si (silicon), in order to manufacture a SiC semiconductor device with reduced current fluctuation while suppressing increases in manufacturing costs, it is required to predict the current fluctuation during the manufacturing process.

Next, a method of manufacturing the SiC semiconductor device according to this embodiment and a method of predicting the amount of fluctuation in current will be described. The growth of an epitaxial layer made of SiC and the formation of MOSFET with a trench gate structure will be omitted in this specification, and may be referred to known processes.

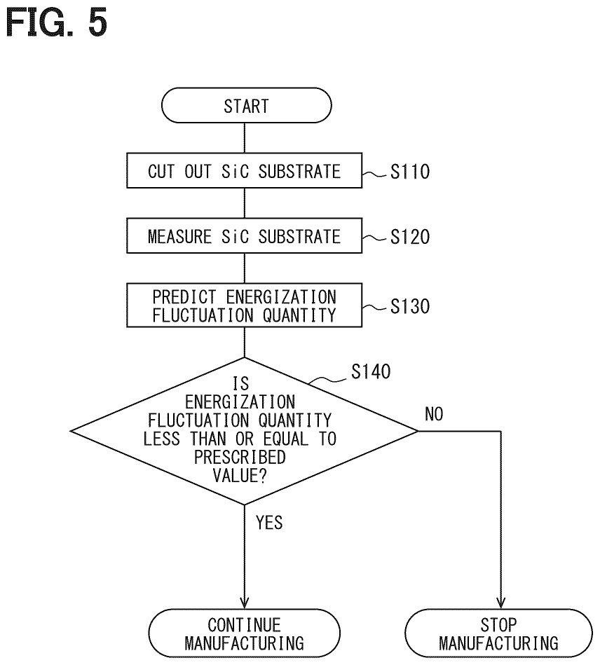

For example, the SiC semiconductor device of this embodiment is manufactured through steps shown in FIG. 5. In step S110, plural semiconductor substrates 11 are cut out from an ingot made of SiC.

In step S120, at least the density of BPDs is measured for a representative one of the semiconductor substrates 11. In the measuring of the density of BPDs, wet etching is performed on the surface of the semiconductor substrate 11 using potassium hydroxide (KOH). Then, the number of depressions, i.e., etch pits, on the surface after the etching is counted, and the number per unit area is calculated. Specifically, for example, the BPD density can be obtained by imaging the surface of the semiconductor substrate 11 after the KOH etching and analyzing the image by a known image analysis technique.

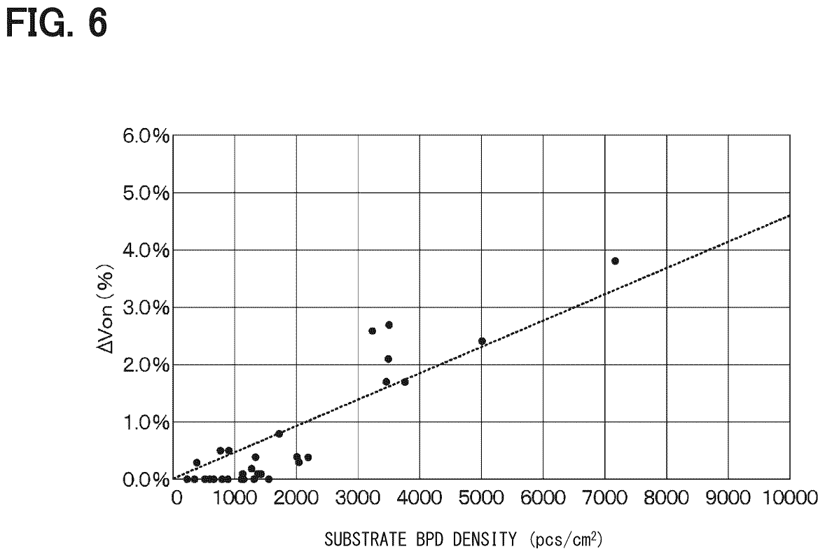

In step S130, an energization fluctuation quantity is predicted based on at least the BPD density when it is assumed that the semiconductor chip 10 is manufactured using the semiconductor substrate 11 cut out in step S110. For example, in step S130, a determination model configured by a predetermined calculation formula or a machine learning model is used to predict the energization fluctuation quantity based on at least the BPD density. Specifically, the BPD density of the semiconductor substrate 11 is measured, and data is obtained on the ratio of a variation ΔVon of the voltage Von after a predetermined period of operation, relative to the initial voltage Von of the MOSFET of the semiconductor chip 10 manufactured using the semiconductor substrate 11 with that BPD density. The relationship between the previously acquired BPD density and the ratio of the variation ΔVon to the initial voltage Von of the semiconductor chip 10 is, for example, as shown in FIG. 6. The results shown in FIG. 6 suggest that there is a certain correlation between the BPD density of the semiconductor substrate 11 and the value ΔVon obtained based on the voltage Von after a predetermined period of operation and the initial value of the voltage, in the semiconductor chip 10 manufactured using the semiconductor substrate 11 having that BPD density, and that it is possible to predict the energization fluctuation quantity based on the BPD density. Then, using the determination model constructed based on the relationship data between the BPD density and the energization fluctuation quantity, the energization fluctuation quantity of the semiconductor chip 10 is predicted during the manufacture of the semiconductor chip 10. As the determination model, for example, a formula for a multiple regression analysis method derived from the above-mentioned relationship data acquired in advance and having BPD density as at least one variable, or any machine learning model using the relationship data as learning data can be used. As the machine learning model, for example, a known method such as a support vector machine, a neural network, a random forest, or a k-nearest neighbor method can be used.

The determination model is stored, for example, in a storage medium of an electronic control unit having various electronic components such as ROM, RAM, and I/O mounted on a circuit board (not shown), and is read from the storage medium and executed as needed. In addition, the driving conditions such as a predetermined energizing time, voltage, temperature, etc. in the data of the energization fluctuation quantity (e.g., AVon/the initial value of Von) acquired in advance before step S130 are appropriately set depending on the application, usage environment, and required performance of the SiC semiconductor device. The energization fluctuation quantity is an amount of fluctuation in electrical characteristics after the switching element is driven for a predetermined time relative to an initial value of electrical characteristics of the switching element immediately after a semiconductor chip having the switching element is manufactured. The fluctuation amount may be directly used, or may be divided by the initial value of Von as the ratio. The data on the energization fluctuation quantity acquired in advance to predict the energization fluctuation quantity is not limited to the value such as ΔVon or Von, but other electrical characteristics such as a value obtained based on ΔVf or the initial value of Vf of the built-in diode may also be used.

In step S140, it is determined whether the energization fluctuation quantity predicted in step S130 is less than or equal to a prescribed value. This determination is made, for example, by a determination program recorded in an electronic control unit in which the determination model used in step S130 is stored. If it is determined that the energization fluctuation quantity predicted in step S130 is equal to or smaller than a prescribed value in step S140, the energization fluctuation quantity after driving for a predetermined period of time or more is small and the reliability of the electrical characteristics is expected to be high. Therefore, the manufacture of the SiC semiconductor device using the semiconductor substrate 11 cut out in step S110 is continued. If it is not determined that the energization fluctuation quantity predicted in step S130 is equal to or smaller than a prescribed value in step S140, the energization fluctuation quantity after driving for a predetermined period of time or more is large and the reliability of the electrical characteristics is expected to be low. Therefore, the manufacture of the SiC semiconductor device using the semiconductor substrate 11 cut out in step S110 is stopped. The threshold value used in the determination in step S140 is set appropriately depending on, for example, the performance requirements of the SiC semiconductor device to be manufactured. This makes it possible to minimize the production of SiC semiconductor devices and reduce the production costs, while manufacturing SiC semiconductor devices in which the energization fluctuation quantity is kept below a predetermined level.

The BPD density is measured in step S120, and the energization fluctuation quantity is predicted based on at least the BPD density in step S130, but not limited to this. In order to further improve the prediction accuracy of the energization fluctuation quantity, other parameters may also be measured and the energization fluctuation quantity may be predicted using the other parameters in addition to the BPD density.

For example, by taking into account the type of BPD in addition to the BPD density, the prediction accuracy of the energization fluctuation quantity can be further improved. The BPDs are classified into a total of 72 types based on the 12 orientations and 6 Burgers vectors b in hexagonal SiC. Specifically, the orientations are 12 axial directions: [11-20], [−12-10], [−2110], [−1-120], [1-210], [2-1-2010], [10-10], [01-10], [1-100], [−1010], [0-110], and [−1100]. There are three Burgers vectors b: (1/3)[11-20], (1/3)[−2110], and (1/3)[1-210]. For each of these three, there are two further types depending on the loop direction. That is, the Burgers vector b has a total of six axial directions.

The above-described notations in parentheses such as [11-20] refer to Miller indices. In addition, the “-” (bar) in the notation of the Miller index should be placed above the desired number, but due to the limitations on expression based on electronic filing, in this specification, it is placed before the desired number.

The orientation of the BPDs can be obtained, for example, by observing the surface after etching with KOH. The Burgers vector b can be measured by a non-destructive inspection such as an X-ray topography method or a PL (photoluminescence) imaging method. The type of BPD can be determined by analyzing, for example, images obtained after KOH etching or images obtained by X-ray topography or PL imaging using a known image recognition technique. In addition, by using the above images and analysis results obtained by various methods as training data and a deep learning model such as deep learning, the accuracy of distinguishing BPD types can be further improved.

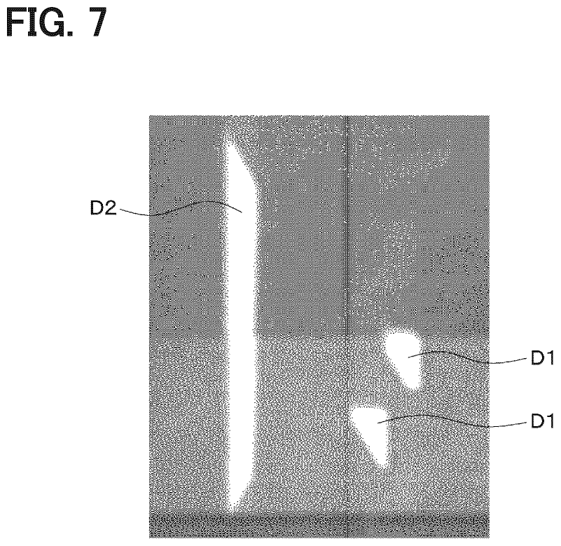

According to the above-mentioned types, the BPDs are classified into those in which a triangular defect D1 grows, those in which a band-shaped defect D2 grows, and those in which the defect D does not grow. As shown in FIG. 7, the band-shaped defect D2 has a larger area than the triangular defect D1. Therefore, the band-shaped defect D2 has a large effect on the energization fluctuation quantity. For example, a BPD with a Burgers vector b of (1/3)[−2110] grows as a band-shaped defect D2 in the orientations of [11-20], [−12-10], [2-1-2010], [10-10], [01-10], [1-100], and [−1100]. In addition, a BPD with a Burgers vector b of (1/3)[1-210] grows as a band-shaped defect D2 in the orientations of [−2110], [−1-120], [1-210], [1-100], [−1010], [0-110], or [−1100]. That is, 28 out of 72 types of BPD grow as the band-shaped defects D2. Therefore, the prediction accuracy can be further improved by predicting the energization fluctuation quantity based on two parameters, e.g., the BPD density and the BPD type.

For example, relationship data is obtained in advance regarding 28 types of BPD that grow as the band-shaped defects D2 out of 72 types of BPD and the energization fluctuation quantity (for example, a value calculated based on ΔVon and the initial value of Von, etc.). In addition, as a determination model, for example, a formula for calculating the energization fluctuation quantity using multiple regression analysis with BPD density and BPD type as variables, and a machine learning model for predicting the energization fluctuation quantity using relationship data between BPD density/type and the energization fluctuation quantity as training data are constructed. Then, in step S130, the energization fluctuation quantity can be predicted based on the BPD density measured in step S120 and BPD the type of the semiconductor substrate 11.

In this case, the BPD density may be calculated using only the 28 types of BPDs in which the band-shaped defects D2 grow, but it may also be calculated without distinguishing between the types of BPDs and used in combination. Furthermore, the type of BPD in which the triangular defect D1 grows may be used to predict the energization fluctuation quantity.

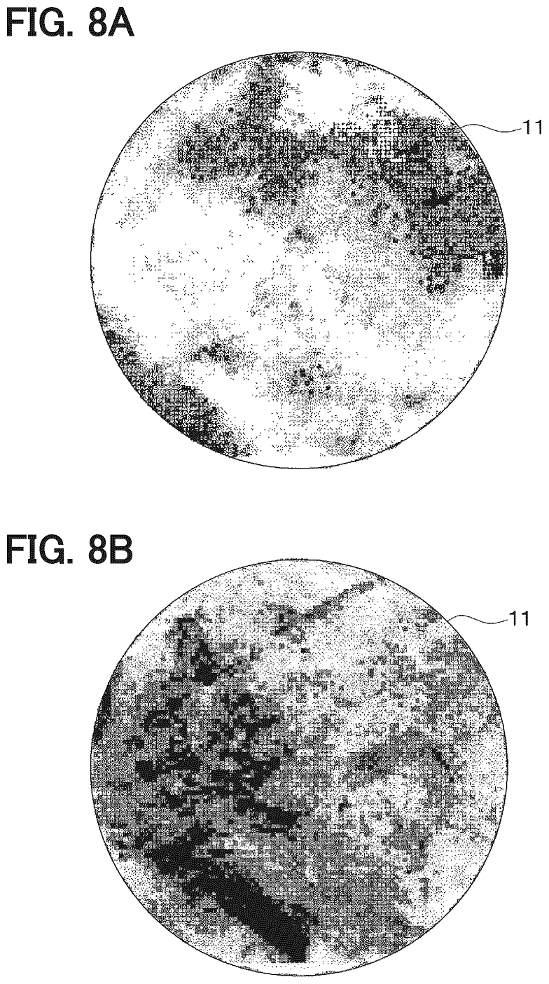

As shown in FIG. 8A and FIG. 8B, the BPD density has a distribution within the surface of the semiconductor substrate 11. In FIGS. 8A and 8B, the distribution of BPD density within the surface of the semiconductor substrate 11 is shown with regions with lower BPD density being shown in a color closer to white and regions with higher BPD density being shown in a color closer to black. The BPD density distributions shown in FIGS. 8A and 8B are for the semiconductor substrates 11 cut from different SiC ingots. In this way, when there is a distribution in the BPD density, the semiconductor substrate 11 may be in a state where only some regions have a predicted energization fluctuation quantity equal to or less than a predetermined threshold value. For example, in such a case, it is determined that the energization fluctuation quantity is lower than or equal to the threshold in step S140, and the manufacture of the SiC semiconductor device is continued. It is possible to pick up the semiconductor chip 10 manufactured in the portion where the predicted energization fluctuation quantity is equal to or less than the threshold value. If the predicted energization fluctuation quantity for a predetermined or larger region of the semiconductor substrate 11 (for example, 80% or more, although this is not limited thereto) exceeds a predetermined threshold value, it is not determined that the energization fluctuation quantity is lower than or equal to the threshold in step S140, and the manufacture of a SiC semiconductor device using the semiconductor substrate 11 is discontinued.

Furthermore, in step S130, the impurity concentration of the semiconductor substrate 11 may be used as one of the parameters for predicting the energization fluctuation quantity. In this case, relationship data between the impurity concentration of the semiconductor substrate 11 and the energization fluctuation quantity in the semiconductor chip 10 manufactured using the semiconductor substrate 11 is acquired in advance, and a determination model is constructed using the relationship data. Then, in step S130, the impurity concentration of the semiconductor substrate 11 may be used as one of the parameters for predicting the energization fluctuation quantity.

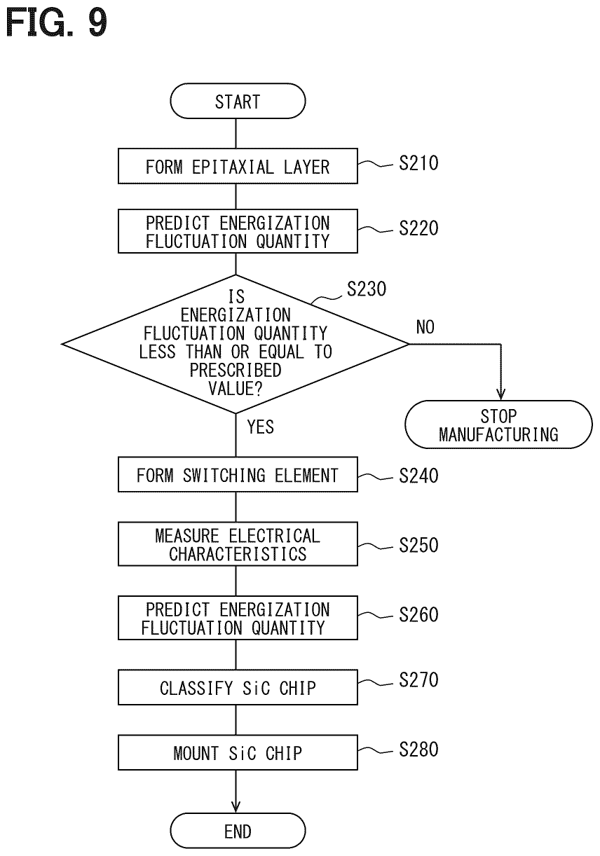

Next, the manufacturing process of the SiC semiconductor device subsequent to the flow chart shown in FIG. 5 will be described with reference to FIG. 9.

In step S210, an epitaxial layer is grown on the semiconductor substrate 11 for which the energization fluctuation quantity predicted in step S140 is equal to or less than the threshold value or the proportion of the region equal to or less than the threshold value is equal to or greater than a predetermined ratio, thereby forming the buffer layer 12 and the low concentration layer 13. For ease of explanation, the semiconductor substrate 11 on which an epitaxial layer is formed will be referred to as a SiC wafer hereinafter. The SiC wafer may also be referred to as a SiC epi-wafer.

In step S220, the energization fluctuation quantity is predicted when it is assumed that the semiconductor chip 10 is manufactured using the SiC wafer. For example, data on the energization fluctuation quantity in the semiconductor chip 10 relative to the parameters of the impurity concentration and thickness in the buffer layer 12 and the impurity concentration and thickness in the low concentration layer 13 that constitutes the drift layer 18 is previously obtained. Furthermore, data on the impurity concentration and thickness of each of the buffer layer 12 and the low concentration layer 13 in the SiC wafer formed in step S210 is recorded, for example, in a storage medium (not shown). The determination model for predicting the energization fluctuation quantity in step S220 is configured to use, in addition to the BPD density, at least one of the impurity concentration and thickness in each of the buffer layer 12 and the low concentration layer 13 as a parameter for predicting the energization fluctuation quantity. The determination model used in step S220 is, for example, similar to the determination model used in step S130, a model using multiple regression analysis or an arbitrary machine learning model.

In step S230, it is determined whether the energization fluctuation quantity predicted in step S220 is less than or equal to a prescribed value. This determination is made, for example, by a determination program recorded in the electronic control unit in which the determination model used in step S220 is stored. If the determination in step S230 is positive, that is, if the reliability is expected to be high, the electronic control unit proceeds to step S240, and the manufacture of SiC semiconductor device using the SiC wafer formed in step S210 is continued. If the determination in step S230 is negative, that is, if the reliability is expected to be low, the manufacture of the SiC semiconductor device using the SiC wafer formed in step S210 is stopped. The threshold value used in the determination of step S230 is set appropriately according to the required performance of the SiC semiconductor device to be manufactured, similar to the threshold value used in the determination of step S140.

In step S240, for example, the JFET portion 14, the first deep layer 15, the current spreading layer 16, the second deep layer 17, the base layer 19, the source region 20, and the contact region 21 are formed on the SiC wafer. In step S240, for example, the trench gate structure, the source electrode 26, the drain electrode 27, and the guard ring (not shown) in the periphery region are formed to form the semiconductor chips 10 having the MOSFET. The parameters of each layer formed in step S240 are recorded, for example, on a storage medium (not shown) and are used to predict the energization fluctuation quantity in step S260, which will be described later. The parameters of each layer include, for example, the impurity concentration and width in the JFET portion 14, the pitch between the trench gate structures in the cell region, the impurity concentration and thickness in the first deep layer 15 and the second deep layer 17, and the like. The parameters of each layer include the impurity concentration and width of the source region 20 and the contact region 21.

In step S250, various electrical characteristics, such as Vf, Von, and I-V characteristics, are measured for the multiple semiconductor chips 10 formed in step S240. The initial electrical characteristics of the semiconductor chips 10 obtained in step S250 are recorded, for example, in a storage medium (not shown) and used as one of the parameters for predicting the energization fluctuation quantity in step S260.

In step S260, for example, a determination model is used to predict the energization fluctuation quantity for the semiconductor chips 10 using at least one of the various parameters obtained in steps S240 and S250 in addition to the BPD density. Specifically, data on the relationship between various parameters such as the impurity concentration, thickness, width, and pitch of the trench gate structure in each layer of the MOSFET formed in step S240 and the actual energization fluctuation quantity is obtained in advance. Furthermore, data on the relationship between the initial values of various electrical characteristics of the semiconductor chip 10 manufactured in step S250 and the actual energization fluctuation quantity is obtained in advance. Then, based on this relationship data in addition to the BPD density, a determination model is constructed to predict the energization fluctuation quantity using at least one of various parameters such as the impurity concentration of each layer on the epitaxial wafer layer and the initial electrical characteristics of the semiconductor chip 10. In step S260, the energization fluctuation quantity is predicted using such a determination model.

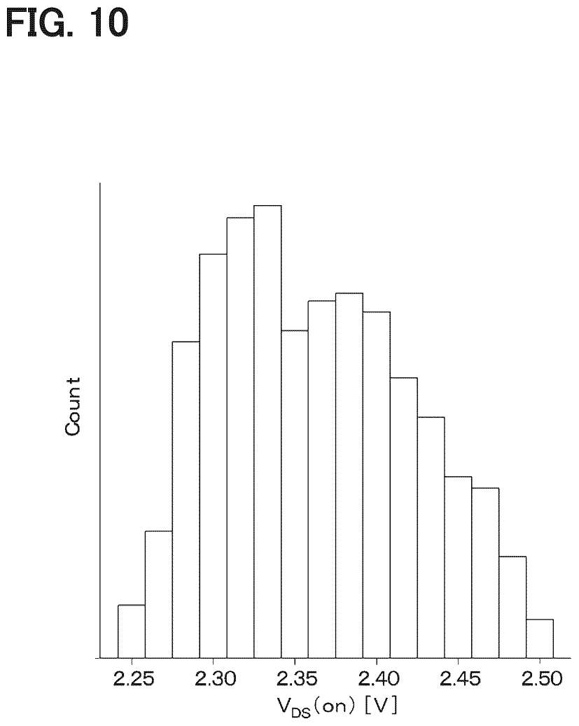

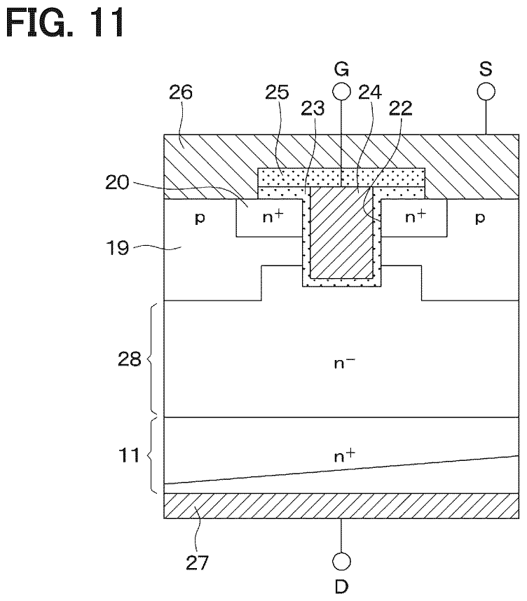

In step S270, the semiconductor chips 10 are classified according to the energization fluctuation quantity predicted in step S260. This classification process is executed, for example, by a program recorded in an electronic control unit in which the determination model used in step S260 is stored. For example, as shown in FIG. 10, the semiconductor chips 10 formed on one wafer exhibit variations in voltage Von between the source electrode 26 and the drain electrode 27, represented as V_{DS}(on) in FIG. 10, which is one of the initial electrical characteristics. In the graph shown in FIG. 10, the horizontal axis represents the initial voltage Von (unit: V), and the vertical axis represents the number (Count) of the chips. As the semiconductor chip 10 is operated, the defects D grow inside the chip, causing the voltage Von to shift to the high voltage side. In step S270, the semiconductor chips 10 are classified, for example, according to the difference between the “fluctuated Von”, which is the voltage Von obtained from the initial voltage Von and the predicted energization fluctuation quantity (ΔVon), and the “required Von”, which is the voltage Von required for the SiC semiconductor device. For example, a group of voltages in which the difference is small relative to the required Von, i.e., with the highest performance, is ranked 1. A group of voltages with the next smallest difference after rank 1 is ranked 2, and so on, according to the predicted performance after the fluctuation. A group that does not satisfy the required performance in step S270, that is, the semiconductor chips 10 classified as NG rank, are excluded without proceeding to step S280.

In step S280, for example, the semiconductor chips 10 sorted in step S270 are mounted on a lead frame or the like, and resin sealing or the like is performed to manufacture a SiC semiconductor device. At this time, the semiconductor chip 10 is used, for example, in a SiC semiconductor device for a purpose corresponding to the rank classified in step S270. For example, one example of step S270 may be to apply the highest performance rank to an in-vehicle application, but is not limited to this.

The above is a basic manufacturing process of the SiC semiconductor device of this embodiment. In step S270, Von is used as the energization fluctuation quantity in classifying the semiconductor chip 10, but not limited to this. The energization fluctuation quantity of other electrical characteristics may be used as an index depending on the required performance.

According to this embodiment, at each stage of cutting the semiconductor substrate 11 from the SiC ingot, growing the epitaxial layer, and forming the MOSFET with trench gate structure, the energization fluctuation quantity of the semiconductor chip 10 that is finally manufactured is predicted based on at least the BPD density. Then, when the predicted energization fluctuation quantity is equal to or less than a prescribed amount, the manufacture of the SiC semiconductor device is continued. This makes it possible to predict the energization fluctuation quantity and reflect the predicted energization fluctuation quantity in the manufacturing process to determine whether or not to continue, resulting in a manufacturing method for a SiC semiconductor device in which the energization fluctuation quantity is suppressed while keeping manufacturing costs down.

The present embodiment also provides the following effects.
(1) By identifying the type of BPD in the semiconductor substrate 11 and predicting the energization fluctuation quantity based on the BPD density and the type of BPD, it is possible to predict the energization fluctuation quantity with higher accuracy.
(2) In determining the type of BPD, image recognition using an image obtained by capturing an image of the semiconductor substrate 11 is performed, thereby improving the accuracy of determining the type of BPD.
(3) The accuracy of predicting the energization fluctuation quantity is improved by using at least one of the BPD type, the impurity concentration in the semiconductor substrate 11, the impurity concentration and thickness in the buffer layer 12, and the impurity concentration and thickness in the drift layer 18, as well as the BPD density, as parameters. The accuracy of predicting the energization fluctuation quantity can be further improved by using at least one of the impurity concentration and thickness in the base layer 19, the impurity concentration and width in the source region 20 or the contact region 21, and the initial electrical characteristics of the semiconductor chip 10 as parameters of the determination model. That is, the energization fluctuation quantity can be predicted with higher accuracy based on two or more parameters including the BPD density, compared with a case where the prediction is made based only on the BPD density.
(4) When predicting the energization fluctuation quantity, the prediction accuracy of the energization fluctuation quantity is improved by using a determination model based on multiple regression analysis or a machine learning model.
(5) The manufactured semiconductor chips 10 are classified according to the predicted energization fluctuation quantity, and the classified semiconductor chips 10 are used in SiC semiconductor devices for purposes corresponding to the classification. Thus, the manufacturing of SiC semiconductor devices can be restricted from being carried out more than necessary, and makes it possible to manufacture SiC semiconductor devices with reduced current fluctuations while reducing manufacturing costs.

### Other Embodiments

Although the present disclosure has been described in accordance with the embodiments, it is understood that the present disclosure is not limited to such embodiments or structures. The present disclosure also includes various modifications and modifications within an equivalent range. In addition, various combinations and modes, and further, other combinations and modes including one element of these alone, or thereabove, or therebelow, are also comprised within the scope or concept range of the present disclosure.

In the embodiment, the semiconductor chip 10 having the JFET portion 14 and the deep layer 15, 17 is used as the SiC semiconductor device, but not limited to this. For example, as shown in FIG. 11, when the semiconductor chip 10 does not have a JFET portion 14 or a deep layer 15, 17, the parameters used to predict the energization fluctuation quantity may be limited to the conditions of the components of the semiconductor chip 10. For example, in addition to the BPD density of the semiconductor substrate 11, at least one of the BPD type, the impurity concentration of the semiconductor substrate 11, and the impurity concentration and thickness or width of the drift layer 28, the base layer 19, and the source region 20 may be used as prediction parameters. In this way, the parameters used to predict the energization fluctuation quantity may be changed as appropriate depending on the configuration of the semiconductor chip 10. The drift layer 28 may not include at least the JFET portion 14.

The control unit (e.g., the electronic control unit in which the determination model is recorded) and the method described in the present disclosure may be realized by a special-purpose computer provided by configuring a processor and memory programmed to perform one or more functions embodied in a computer program. Alternatively, the control unit and the method described in the present disclosure may be realized by a dedicated computer provided by configuring a processor with one or more dedicated hardware logic circuits. Alternatively, the control unit and the method described in the present disclosure may be implemented by one or more special purpose computer, which is configured as a combination of a processor and a memory, which are programmed to perform one or more functions, and a processor which is configured with one or more hardware logic circuits. Furthermore, the computer program may be stored in a computer-readable non-transitory tangible storage medium as an instruction executed by a computer.

The constituent element(s) of each of the embodiments is/are not necessarily essential unless it is specifically stated that the constituent element(s) is/are essential in the embodiment, or unless the constituent element(s) is/are obviously essential in principle. A quantity, a value, an amount, a range, or the like referred to in the description of the embodiment is not necessarily limited to such a specific value, amount, range or the like unless it is specifically described as essential or understood as being essential in principle. Furthermore, a shape, positional relationship or the like of a structural element, which is referred to in the embodiment, is not limited to such a shape, positional relationship or the like, unless it is specifically described or obviously necessary to be limited in principle.

What is claimed is:

1. A method of manufacturing a silicon carbide semiconductor device having a switching element on a semiconductor substrate made of silicon carbide to have a built-in diode, the method comprising:
measuring a BPD density which is a density of basal plane dislocation in the semiconductor substrate;
predicting an energization fluctuation quantity based on at least the BPD density, the energization fluctuation quantity being an amount of fluctuation in electrical characteristics after the switching element is driven for a predetermined time relative to an initial value of electrical characteristics of the switching element immediately after a semiconductor chip having the switching element is manufactured; and
determining whether or not to continue manufacturing the silicon carbide semiconductor device using the semiconductor substrate based on the energization fluctuation quantity.

2. The method according to claim 1, further comprising: determining a BPD type, which is a type of basal plane dislocation, wherein the energization fluctuation quantity is predicted based on the BPD density and the BPD type.

3. The method according to claim 2, wherein the BPD type is determined by an image recognition using an image obtained by imaging the semiconductor substrate.

4. The method according to claim 1, further comprising: forming a silicon carbide wafer by stacking a buffer layer and a drift layer on the semiconductor substrate, wherein
the energization fluctuation quantity is predicted based on the BPD density and at least one of a BPD type, which is a type of basal plane dislocation, an impurity concentration of the semiconductor substrate, an impurity concentration and a thickness of the buffer layer, and an impurity concentration and a thickness of the drift layer, and
determining whether or not to continue manufacturing the silicon carbide semiconductor device using the silicon carbide wafer.

5. The method according to claim 4, wherein the energization fluctuation quantity is predicted by using a determination model previously trained by machine learning.

6. The method according to claim 4, wherein the energization fluctuation quantity is predicted by using a determination model based on multiple regression analysis having at least the BPD density as one of variables.

7. The method according to claim 5 further comprising: forming a base layer, a source region, and a contact region on the silicon carbide wafer to manufacture the semiconductor chip which is one of a plurality of semiconductor chips, wherein
the energization fluctuation quantity is predicted by using the determination model based on at least three or more of the BPD density, the BPD type, an impurity concentration of the semiconductor substrate, an impurity concentration and a thickness of the buffer layer, an impurity concentration and a thickness of the drift layer, an impurity concentration and a width of the source region, an impurity concentration and a width of the contact region, and initial electrical characteristics of the switching element.

8. The method according to claim 7, further comprising: forming a JFET portion and a deep layer on the silicon carbide wafer, in a manufacturing of the plurality of semiconductor chips, wherein
the energization fluctuation quantity is predicted by using the determination model based on at least three or more of the BPD density, the BPD type, an impurity concentration of the semiconductor substrate, an impurity concentration and a thickness of the buffer layer, an impurity concentration and a thickness of the drift layer, an impurity concentration and a width of the JFET portion, an impurity concentration of the deep layer, an impurity concentration and a width of the source region, an impurity concentration and a width of the contact region, and initial electrical characteristics of the switching element.

9. The method according to claim 7, further comprising: classifying the plurality of semiconductor chips according to a predicted value of the energization fluctuation quantity.
